(19) United States
(12) Patent Application Publication
(10) Pub. No.: US 2007/0246726 A1
(43) Pub. Date: Oct. 25, 2007

(54) Package structure of light emitting device

(76) Inventor: San Bao Lin, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/723,560

(22) Filed: Mar. 21, 2007

(30) Foreign Application Priority Data
Apr. 20, 2006 (TW) 095114074

(51) Int. Cl. H01L 33/00

(52) U.S. Cl. 257/99

(57) ABSTRACT

The present invention relates to a package structure of light emitting device, comprising a light emitting diode disposed on a submount, wherein the light emitting diode comprises a first contact and a second contact respectively connected with a first conductive lead and a second conductive lead of the submount. The first conductive lead and second conductive lead of the submount are electrically connected with a print circuit board. As a result, the light emitting diode is electrically connected with the print circuit board without the wire bonding process, and the power can be supplied to the light emitting diode through the print circuit board.

### FIELD OF THE INVENTION

The present invention relates to a package structure, and more particularly to a package structure of light emitting device, which can be used according to power supplied through the print circuit board, such that the manufacturing process and structure of the light emitting device can be simplified.

### BACKGROUND

The light emitting diode (LED) has advantages of long lifetime, small size, short reaction time and without radiation, hence it has come to play a critical role in numerous application, such as indicator lights, lamps, traffic lights, flat-panel displays, optical communications and so on. A Light emitting diode (LED) comprises advantages of long lifetime, small volume, low power consumption, high speed response time, non-heat radiation, and single color light emitting; therefore, such is applied in the fields of indication light, billboard, traffic lights, vehicle lamp, display panel, communication tool, consuming electrical production, and so on.

Referring to FIG. 1 is a cross sectional view of the prior art light emitting device. The light emitting device 10 comprises a light emitting diode 15 and a leadframe 13 electrically connected, wherein the light emitting diode 15 comprises a first material layer 151 and a second material layer 153 attached as a stack. For example, the first material layer 151 is an N-type semiconductor material, the second material layer 153 is a P-type semiconductor material, such that a PN junction is sandwiched between the first material layer 151 and the second material layer 153 spontaneously, thus, the light emitting diode 15 can be emitted, while a voltage is applied between the first material layer 151 and the second material layer 153.

The heat generated during the light emitting process may damage the luminous efficiency of the light emitting diode 15, if that does not be extracted. In general, the light emitting diode 15 is disposed on a heat sink 11 for extracting the heat; for example, the heat can be transmitted into the heat sink 11 from the light emitting diode 15 to avoid temperature increasing during the light emitting period.

The light emitting diode 15 is electrically connected with the leadframe 13 via the conductive wire 16 for supplying power to the light emitting diode 15 from the leadframe 13, and that can simplify the power supply circuit and provide convenience for using.

In the structure of above embodiment, the light emitting diode 15 connects to the leadframe 13 via the conductive wire 16, according to the connection, the conductive wire 16 may be fell off during the manufacturing, light emitting, or temperature alternating. For example, a transparent protection layer 18 made of silicone is disposed over the light emitting diode 15 in the manufacturing process for protecting the light emitting diode 15. However, the transparent protection layer 18 is a supple material, and the shape of that may be changed by external force. When the shape of the transparent protection layer 18 is changed, the external force is transmitted into the light emitting device 10 to break the structure of the conductive wire 16, such that the yield and durability of the light emitting device 10 may be decreased.

An isolating module 14 is used to cover the leadframe 13 that comprises a first leadframe 131 and a second leadframe 133 to steady the first leadframe 131 and second leadframe 133. However, the manufacture of leadframe 13 may increase the fabricating process step and cost regarding to the light emitting device 10, and cannot be used for improving the fabricating efficiency.

### SUMMARY OF THE INVENTION

Accordingly, the key point of the present invention discloses a novel package structure of package structure of light emitting device, not only omitting the leadframe in the manufacturing process of the light emitting device, but also completing the electrical connection of the light emitting diode without the conductive wire.

It is a primary object of the present invention to provide a package structure of light emitting device, wherein a print circuit board comprises at least one cavity for containing at least one light emitting diode, therefore, the print circuit board can be used to supply power to the light emitting diode without the leadframe, furthermore, the manufacturing process can be simplified and the manufacturing cost can be reduced.

It is a secondary object of the present invention to provide a package structure of light emitting device, wherein the submount is connected with the print circuit board, and the wire bonding process can be omitted in the manufacturing process of light emitting device for reducing the manufacturing cost.

It is another object of the present invention to provide a package structure of light emitting device, wherein the light emitting device is connected with a heat sink for extracting the heat generated during light emitting period from the light emitting diode.

It is another object of the present invention to provide a package structure of light emitting device, wherein the cavity disposed within the print circuit board contains a plurality of light emitting diodes for mixing the color light of each light emitting diode within the single cavity.

It is another object of the present invention to provide a package structure of light emitting device, wherein the print circuit board comprises a plurality of cavities that contain a light emitting diode to simplify the manufacturing process.

It is another object of the present invention to provide a package structure of light emitting device, wherein the print circuit board comprises a plurality of light emitting diodes arranged in a matrix, such that the light emitting device can be used in many range.

To achieve the above mentioned objects, the present invention provides A package structure of light emitting device, comprising: a submount, comprising at least one first conductive lead and at least one second conductive lead disposed on the submount; at least one light emitting diode comprising a first material layer and a second material layer attached as a stack, at least one first contact disposed on the first material layer to connect with the first conductive lead, and at least one second contact disposed on the second material layer to connect with the second conductive lead; and a print circuit board comprising at least one cavity to contain the light emitting diode, wherein the first conductive lead and second conductive lead are electrically connected with the print circuit board.

### BRIEF DESCRIPTION OF DRAWINGS

FIG. 1 is a cross section view of a prior art package structure of light emitting device.

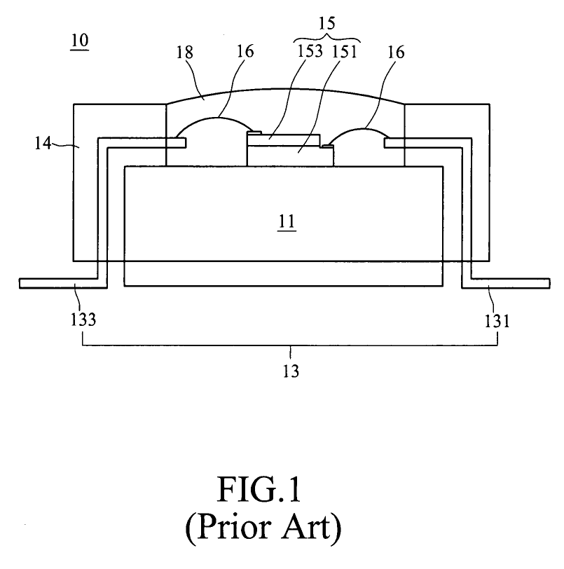

FIG. 2A is a cross section view of an embodiment of the present invention a package structure of light emitting device.

FIG. 2B is a top view of above embodiment of the present invention.

FIG. 3 is a cross section view of another embodiment of the present invention.

FIG. 4 is a cross section view of another embodiment of the present invention.

FIG. 5A is a cross section view of another embodiment of the present invention.

FIG. 5B is top view of above embodiment of the present invention.

### DETAILED DESCRIPTION

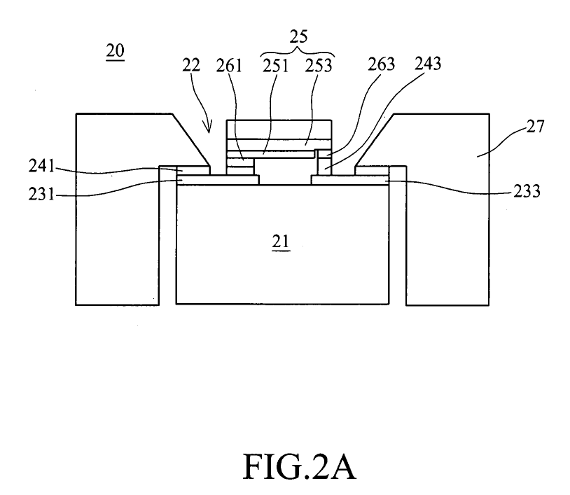

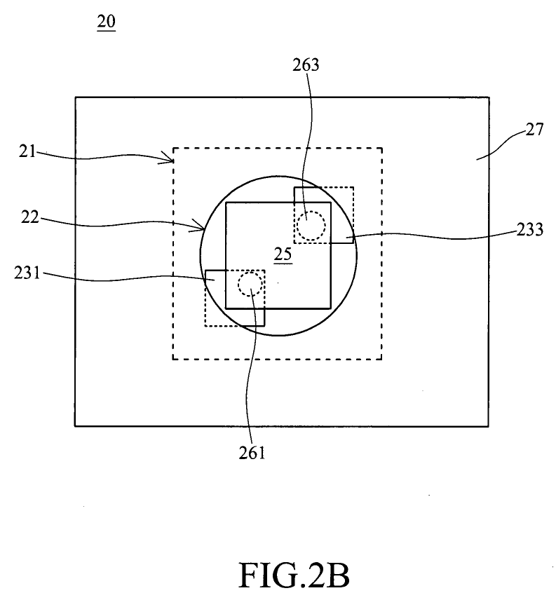

Referring to FIG. 2A and FIG. 2B are respectively a cross section view and top view of an embodiment of the present invention a light emitting device. The light emitting device 20 comprises at least one light emitting diode 25 disposed on a submount 21, and the submount 21 is electrically connected with a print circuit board (PCB) 27 to achieve the purpose of supplying power to the light emitting diode 25.

At least one first conductive lead 231 and at least one second conductive lead 233 disposed on the submount 21 connect with the light emitting diode 25; for example, the light emitting diode 25 is disposed on the submount in flip chip configuration. The light emitting diode 25 comprises a first material layer 251 and a second material layer 253 attached as a stack, at least one first contact 261 disposed on the first material layer 251, and at least one second contact 263 disposed on the second material layer 253. The first contact 261 and the second contact 263 respectively connect with the first conductive lead 231 and the second conductive lead 233, therefore the power can be supplied to the light emitting diode 25 through the first conductive lead 231 and the second conductive lead 233.

The first material layer 251 and the second material layer 253 of the light emitting diode 25 are made of a semiconductor material. For example, the first material layer 251 is an N type semiconductor material, the second material layer 253 is a P type semiconductor material, and a PN junction is sandwiched between the first material layer 251 and the second material layer 253 spontaneously. The PN junction can emit light, while a power signal is supplied between the first material layer 251 and the second material layer 253.

The print circuit board 27 comprises at least one cavity 22 for containing the light emitting diode 25 and/or the submount 21, hence the first conductive lead 231 and the second conductive lead 233 of the submount 21 are respectively electrically connected with the print circuit board 27. For example, the first conductive lead 231 connects with a first circuit (not shown) of the print circuit board 27, and the second conductive lead 233 connects with a second circuit (not shown) of the print circuit board 27. Thus, the print circuit board 27 can be used to supply power to the light emitting diode 25 through the first conductive lead 231 and the second conductive lead 233.

The first conductive lead 231 and the second conductive lead 233 connect with the print circuit board 27 through a first conductive adhesion layer 241 that is made of metal, such as solder paste, tin flakes, tin leafs or tin solder wires. The light emitting diode 25 connects with the first conductive lead 231 and the second conductive lead 233 through a second conductive adhesion layer 243, such as solder ball or eutectic. Comparing with the second conductive adhesion layer 243, the first conductive adhesion layer 241 is formed at lower temperature; such as the first conductive adhesion layer 241 is a lower temperature conductive adhesion layer, and the second conductive adhesion layer 243 is a higher temperature conductive adhesion layer. In another embodiment of the invention, the first conductive adhesion layer 241 and the second conductive adhesion layer 243 can be made of the same material. Furthermore, the submount 21 is made of a high thermal conductivity and low thermal expansion coefficient material, such as ceramics, metal, AlN, Al₂O₃ or CuW.

The circuit of the print circuit board 27 is adjusted with the position of the light emitting diode 25. For example, the cavity 22 is formed within the print circuit board 27 for containing a light emitting diode 25, and the circuit of the print circuit board 27 is electrically connected with the light emitting diode 25, wherein the circuit of the print circuit board 27 is formed by an etching process. Therefore, the light emitting diode 25 disposed within the cavity 22 can be electrically connected with the print circuit board 27 without the leadframe 13 to improve the manufacturing efficiency and decrease the manufacturing cost.

The angle of the cavity 22 can be different, for example 45 degree, and the cavity 22 can be as a reflector for reflecting the light generated by the light emitting diode 25.

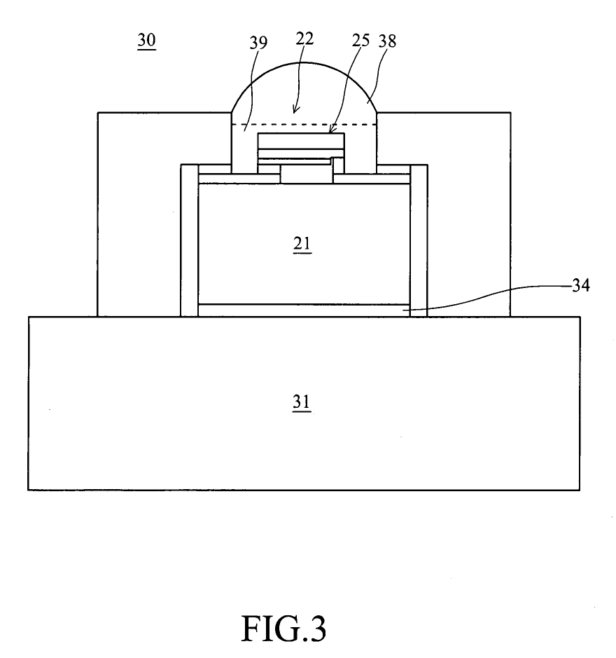

Referring to FIG. 3 is a cross section view of another embodiment of the invention. Comparing with the light emitting device 20 of FIG. 2A, the light emitting device 30 comprises a heat sink 31 for extracting the heat generated during the light emitting process of the light emitting diode 25.

The light emitting diode 25 connects with the heat sink 31 through the submount 21; for example the submount 21 connects with the heat sink 31 by an adhesion layer 34. Besides, the submount 21 is made of an insulating material with high thermal conductivity, and the heat sink 31 is made of a high thermal conductivity material, such as aluminum, copper, silver, or metal. Of course the adhesion layer 34 can be made of a high thermal conductivity material, such as silver pastes, thermal compound, or soldering tins.

The heat generated during the light emitting process of the light emitting diode 25 can be extracted from the submount 21 to the adhesion layer 34 and the heat sink 31 by thermal conduction. Therefore, the heat can be extracted from the light emitting diode 25 fast for improving the luminous efficiency of the light emitting diode 25 advantageously.

A transparent protection layer 38 is disposed over the light emitting diode 25 to achieve the purpose for protecting the light emitting diode 25. Pouring a colloid, such as silicon, into the cavity 22 forms the transparent protection layer 38. In another embodiment of the invention, the shape of the transparent protection layer 38 can be changed in the manufacturing process; for example the shape of the transparent protection layer 38 can be a lens for collecting the emitting light of the light emitting diode 25. Furthermore, a fluorescent layer 39 can be disposed over the light emitting diode 25 for changing the color of the emitting light.

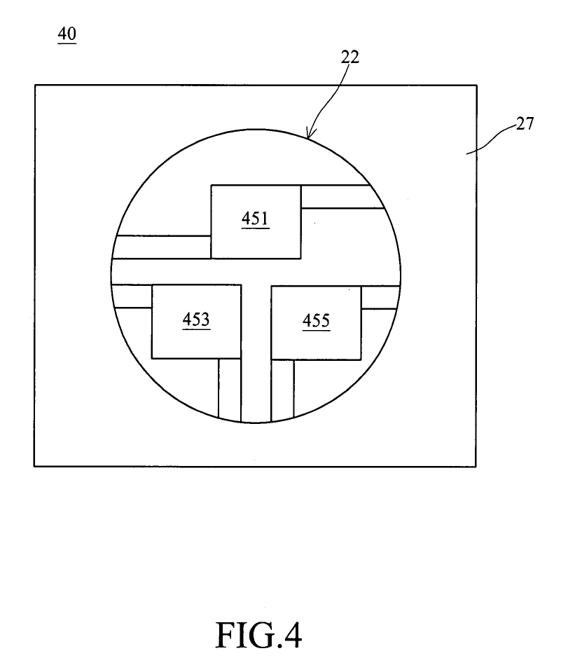

Referring to FIG. 4 is a top view of another embodiment of the invention. The light emitting device 40 comprises a plurality of light emitting diodes disposed within the cavity 22 of the print circuit board 27 for enhancing the brightness of the light emitting device 40. In addition, the plurality of light emitting diodes can be used to emit different color light, and the color light can be mixed within the cavity 22.

Preferably, the number of the light emitting diodes disposed within the cavity 22 of the light emitting device 40 is three. For example, the light emitting device 40 comprises a first light emitting diode 451 for emitting red light, a second light emitting diode 453 for emitting green light, and a third light emitting diode 455 for emitting blue light disposed within the cavity 22. Therefore, the light emitting device 40 can generate a white light or full color light by mixing the red light, the green light, and the blue light.

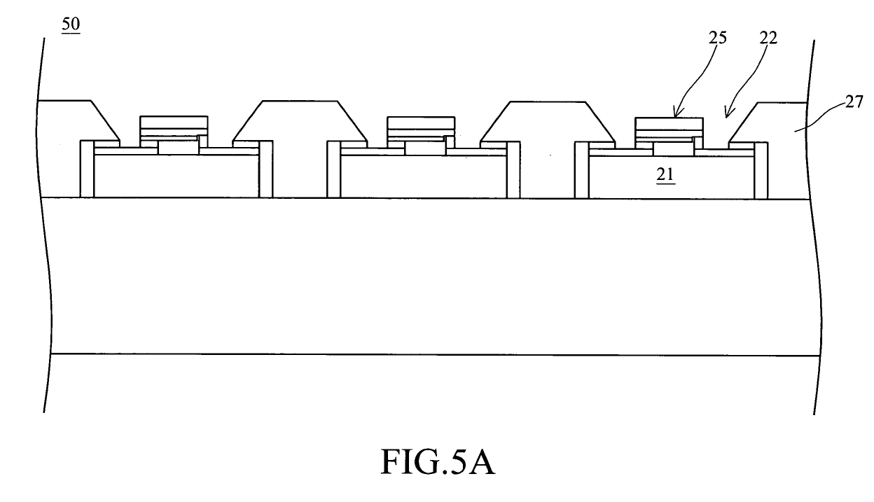

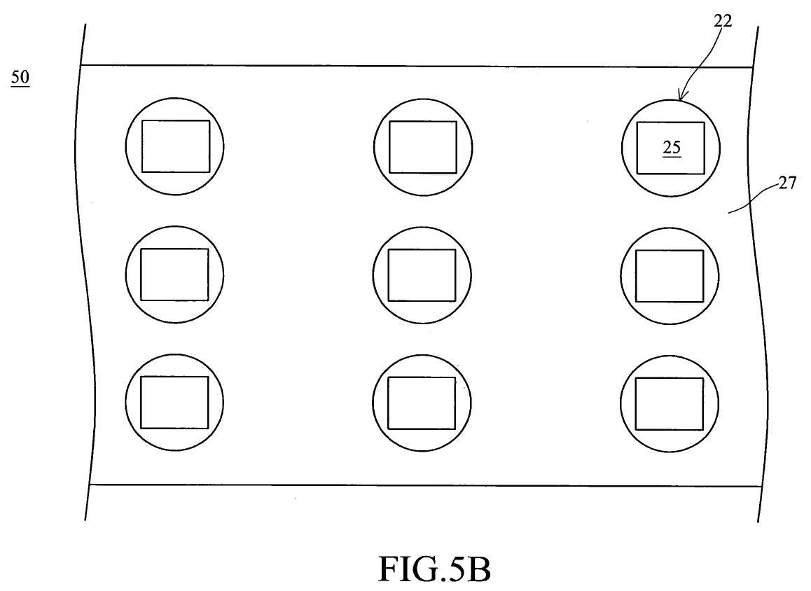

Referring to FIG. 5A and FIG. 5B are respectively a cross section view and top view of another embodiment of the present invention. The light emitting device 50 comprises a plurality of cavities 22 and light emitting diodes 25. For example, a print circuit board 27 comprises a plurality of cavities 22, and each cavity 22 contains a light emitting diode 25.

The light emitting diodes 25 disposed within the print circuit board 27 can be arranged in any shape. For example, as FIG. 5B the light emitting diodes 25 are arranged in a matrix. Therefore, the light emitting device 50 can be suitable for using in many range; for example, the light emitting device 50 can be a plane light source or back light module of a liquid crystal display.

The foregoing description is merely one embodiment of present invention and not considered as restrictive. All equivalent variations and modifications in process, method, feature, and spirit in accordance with the appended claims may be made without in any way from the scope of the invention.

1. A package structure of light emitting device, comprising:
a submount, comprising at least one first conductive lead and at least one second conductive lead disposed on said submount;
at least one light emitting diode provided on said submount, comprising a first material layer and a second material layer attached as a stack, at least one first contact disposed on said first material layer to connect with said first conductive lead, and at least one second contact disposed on said second material layer to connect with said second conductive lead; and
a print circuit board comprising at least one cavity to contain said light emitting diode, wherein said first conductive lead and said second conductive lead are electrically connected with said print circuit board.

2. The package structure of light emitting device of claim 1, wherein said light emitting diode is disposed on said submount in flip chip configuration.

3. The package structure of light emitting device of claim 1, further comprising a fluorescent layer disposed over said light emitting diode.

4. The package structure of light emitting device of claim 1, further comprising a transparent protection layer disposed over said light emitting diode.

5. The package structure of light emitting device of claim 4, wherein said transparent protection layer is a lens.

6. The package structure of light emitting device of claim 1, further comprising a heat sink connected with said submount.

7. The package structure of light emitting device of claim 6, wherein said heat sink is made of metal.

8. The package structure of light emitting device of claim 6, wherein said submount is connected with said heat sink through an adhesion layer.

9. The package structure of light emitting device of claim 1, wherein said first conductive lead and said second conductive lead of said submount are connected with said print circuit board through a first conductive adhesion layer.

10. The package structure of light emitting device of claim 9, wherein said conductive adhesion layer can be one of soldering tins, tin flakes, tin leafs, or tin solder wires.

11. The package structure of light emitting device of claim 1, wherein said light emitting diode is connected with said first conductive lead and said second conductive lead of said submount through a second conductive adhesion layer.

12. The package structure of light emitting device of claim 11, wherein said second conductive adhesion layer can be one of tin solder or eutectic.

13. The package structure of light emitting device of claim 1, wherein the number of said light emitting diode disposed within said cavity is three, and said light emitting diode comprises a first light emitting diode, a second light emitting diode, and a third light emitting diode.

14. The package structure of light emitting device of claim 13, wherein said first light emitting diode emits a red emitting light, said second light emitting diode emits a green emitting light, and said third light emitting diode emits a blue emitting light.

15. The package structure of light emitting device of claim 1, wherein said print circuit board comprises a plurality of said cavities and said light emitting diodes.

16. The package structure of light emitting device of claim 15, wherein said light emitting diodes are arranged in a matrix.

17. The package structure of light emitting device of claim 1, wherein said submount is made of an isolation material with high thermal conductivity.

18. The package structure of light emitting device of claim 1, wherein said submount is disposed within said cavity of said print circuit board.

19. The package structure of light emitting device of claim 1, wherein said submount is made of a high thermal conductivity material with low expansion coefficient.
